(19) United States
(12) Patent Application Publication
(10) Pub. No.: US 2011/0133748 A1
(43) Pub. Date: Jun. 9, 2011

(54) SIGNAL OUTPUT CIRCUIT, TIMING GENERATE CIRCUIT, TEST APPARATUS AND RECEIVER CIRCUIT

(75) Inventors: Yusuke HAYASE, Saitama (JP); Toshiyuki OKAYASU, Saitama (JP)

(73) Assignee: ADVANTEST CORPORATION, Tokyo (JP)

(21) Appl. No.: 12/959,302

(22) Filed: Dec. 2, 2010

Related U.S. Application Data
(63) Continuation of application No. PCT/JP2008/062691, filed on Jul. 14, 2008.

(51) Int. Cl. H03H 11/26; H03K 5/01; G01R 31/02

(52) U.S. Cl. 324/537; 327/100; 327/276

(57) ABSTRACT

Provided is a signal output circuit that outputs a signal, comprising an output circuit that changes a characteristic of a signal output therefrom according to a change in power supply voltage supplied thereto and a control signal supplied thereto; and a control section that changes the control signal to compensate for a change in the characteristic due to a change in the power supply voltage.

### BACKGROUND

1. Technical Field

The present invention relates to a signal output circuit, a timing generation circuit, a test apparatus, and a receiver circuit. In particular, the present invention relates to a signal output circuit whose output signal has characteristics that change according to changes in power supply voltage provided thereto and changes in a control signal provided thereto, a timing generation circuit that outputs a timing signal obtained by delaying the input signal by a delay amount corresponding to a control signal provided thereto, a test apparatus that includes this timing generation circuit, and a receiver circuit that detects the data pattern of an input signal.

2. Related Art

A signal processing circuit, which can be represented by a delay circuit, an amplifier, a filter, or the like, has a function for changing characteristics of an input signal, such as phase, amplitude, and frequency, and outputting the resulting signal, and such a signal processing circuit is widely used in semiconductor circuits, as shown in, for example, Japanese Patent Application Publication No. H10-19990.

A series regulator may be used in a power supply circuit for supplying power supply voltage to the signal processing circuit. It is widely known that energy efficiency can be improved by using a switching regulator, referred to hereinafter as a switching power supply, instead of the series regulator.

However, the voltage generated by a switching power supply includes ripple noise synchronized with the switching period. The amount by which the signal processing circuit changes a characteristic of the input signal often depends on the power supply voltage, and therefore the ripple noise causes an error in the amount of change that cannot be ignored. In the case of a delay circuit, for example, the ripple noise causes jitter to be superimposed on the delay amount applied to the input signal.

### SUMMARY

Therefore, it is an object of an aspect of the innovations herein to provide a signal output circuit, a timing generation circuit, a test apparatus, and a receiver circuit, which are capable of overcoming the above drawbacks accompanying the related art. The above and other objects can be achieved by combinations described in the independent claims. The dependent claims define further advantageous and exemplary combinations of the innovations herein. According to a first aspect related to the innovations herein, provided is a signal output circuit that outputs a signal, comprising an output circuit that changes a characteristic of a signal output therefrom according to a change in power supply voltage supplied thereto and a control signal supplied thereto; and a control section that changes the control signal to compensate for a change in the characteristic due to a change in the power supply voltage.

According to a second aspect related to the innovations herein, provided is a timing generation circuit that generates a timing signal having a predetermined phase, comprising a delay circuit that outputs the timing signal by delaying an input signal by a delay amount corresponding to a control signal supplied thereto, and that changes the delay amount according to a change in power supply voltage supplied thereto; and a control section that changes the control signal to compensate for a change in the delay amount caused by a change in the power supply voltage.

According to a third aspect related to the innovations herein, provided is a test apparatus that tests a device under test, comprising a timing generation circuit that generates the timing signal having a predetermined phase; a signal supplying section that generates a test signal having a phase corresponding to the timing signal and supplies the test signal to the device under test; and a judging section that judges pass/fail of the device under test by detecting operation of the device under test according to the test signal. The timing generation circuit includes a delay circuit that outputs the timing signal by delaying an input signal by a delay amount corresponding to a control signal supplied thereto, and that changes the delay amount according to a change in power supply voltage supplied thereto; and a control section that changes the control signal to compensate for a change in the delay amount caused by a change in the power supply voltage.

According to a fourth aspect related to the innovations herein, provided is a receiver circuit that detects a data pattern of an input signal, comprising a digital converting section that detects a logic value of the input signal according to a clock signal supplied thereto; and a clock generation circuit that generates the clock signal having a predetermined phase. The clock generation circuit includes a delay circuit that outputs the clock signal by delaying a reference signal by a delay amount corresponding to a control signal supplied thereto, and that changes the delay amount according to a change in power supply voltage supplied thereto; and a control section that changes the control signal to compensate for the change in the delay amount caused by a change in the power supply voltage.

The summary clause does not necessarily describe all necessary features of the embodiments of the present invention. The present invention may also be a sub-combination of the features described above.

### BRIEF DESCRIPTION OF THE DRAWINGS

FIG. 1 is a schematic view showing an exemplary configuration of a signal output circuit 10 according to an embodiment of the present invention.

FIG. 2 is a schematic view showing an exemplary configuration of the control section 50.

FIG. 3 shows an exemplary phase relationship between a waveform of the power supply voltage V_{DD} supplied from the switching power supply 40 to the output circuit 20 and a waveform of the control signal S_{CONT} supplied from the control section 50 to the output circuit 20.

FIG. 4 is a schematic view showing an exemplary configuration of the output circuit 20.

FIG. 5 is a schematic view showing another exemplary configuration of the signal output circuit 10.

FIG. 6 is a schematic view showing an exemplary configuration of the control section 50 in the signal output circuit 10 shown in FIG. 5.

FIG. 7 shows an exemplary configuration of a test apparatus 100 according to another embodiment of the present invention.

FIG. 8 shows an exemplary configuration of the timing generation circuit 120.

FIG. 9 shows another exemplary configuration of the timing generation circuit 120.

FIG. 10 shows an exemplary configuration of a receiver circuit 200 according to another embodiment of the present invention.

FIG. 11 shows another exemplary configuration of the receiver circuit 200.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

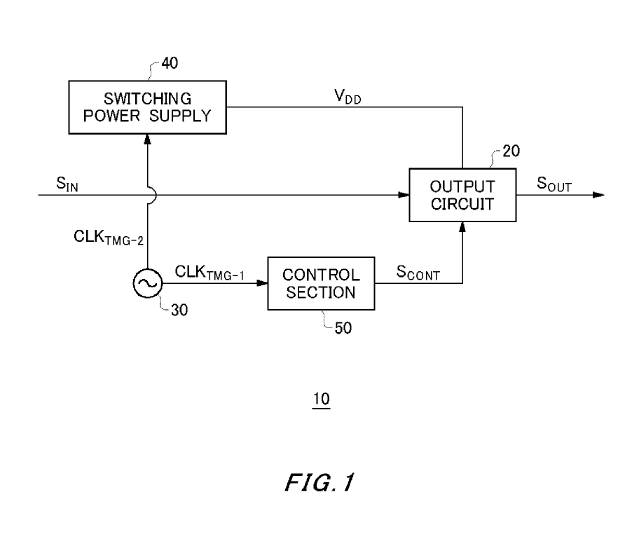

FIG. 1 is a schematic view showing an exemplary configuration of a signal output circuit 10 according to an embodiment of the present invention. The signal output circuit 10 of the present embodiment outputs an output signal S_{OUT}, obtained by performing prescribed signal processing on an input signal S_{IN} received from the outside, to the outside. The prescribed signal processing is processing that changes at least one characteristic of the input signal S_{IN}, such as processing that changes at least one of the phase, the amplitude, and the frequency of the input signal S_{IN}.

The signal output circuit 10 includes an output circuit 20, a timing clock generating section 30, a switching power supply 40, and a control section 50.

The output circuit 20 changes at least one characteristic of the input signal S_{IN} according to a control signal S_{CONT} from the control section 50, and outputs the resulting signal as the output signal S_{OUT}. The output circuit 20 includes at least one of a delay circuit that delays the phase of the input signal S_{IN} by a prescribed amount, an amplifier circuit that amplifies the amplitude of the input signal S_{IN} with a prescribed gain, and a frequency modulation circuit, i.e. a tuner, that modulates the frequency of the input signal S_{IN} by a prescribed ratio.

The timing clock generating section 30 generates a timing clock CLK_{TMG-1} and a timing clock CLK_{TMG-2}, outputs the timing clock CLK_{TMG-1} to the control section 50, and outputs the timing clock CLK_{TMG-2} to the switching power supply 40. The timing clock CLK_{TMG-2} may have a frequency obtained by dividing the frequency of the timing clock CLK_{TMG-1} by N.

The switching power supply 40 outputs a prescribed power supply voltage to the output circuit 20 by switching a power supply ON and OFF according to the timing clock CLK_{TMG-2} from the timing clock generating section 30. The voltage output by the switching power supply 40 is not a constant value, and changes according to the switching operation of the switching power supply 40. Furthermore, ripple noise is superimposed on the voltage output by the switching power supply 40, with a period corresponding to the switching operation.

In the present embodiment, the change amount that the output circuit 20 applies to the characteristic of the input signal S_{IN} changes according to a change in the magnitude of the power supply voltage V_{DD} from the switching power supply 40. For example, if the output circuit 20 includes a delay circuit using a CMOS circuit, the delay amount changes according to a change in the magnitude of the power supply voltage V_{DD} supplied to the CMOS circuit.

The control section 50 outputs the prescribed control signal S_{CONT} to the output circuit 20. The control section 50 may output to the output circuit 20 the control signal S_{CONT} for controlling the change amount that the output circuit 20 applies to the characteristic of the input signal S_{IN}. The control section 50 may change the control signal S_{CONT} based on changes in the power supply voltage V_{DD}.

More specifically, the control section 50 may change the control signal S_{CONT} in a manner to suppress changes in the change amount that the output circuit 20 applies to the characteristic of the input signal S_{IN}, which are caused by changes in the power supply voltage V_{DD} due to the switching operation of the switching power supply 40. The changing of the control signal S_{CONT} by the control section 50 is described in detail further below.

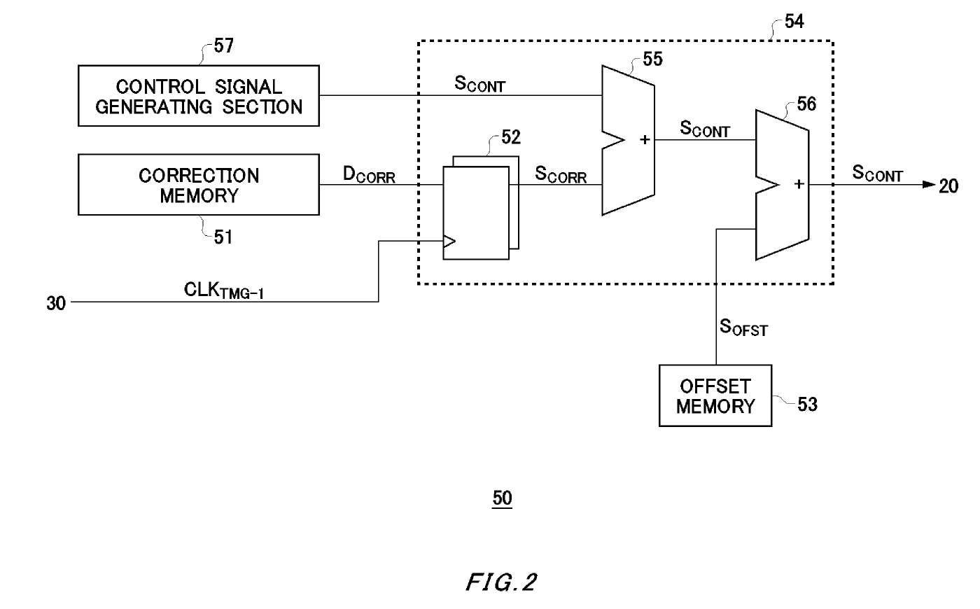

FIG. 2 is a schematic view showing an exemplary configuration of the control section 50. The control section 50 includes a correction memory 51, an offset memory 53, a superimposing section 54, and a control signal generating section 57. The superimposing section 54 includes a correction pattern acquiring section 52, a correction pattern adder 55, and an offset adder 56.

The correction memory 51 stores a correction pattern D_{CORR}. The correction memory 51 may store a correction pattern D_{CORR} for correcting changes in the change amount that the output circuit 20 applies to the characteristic of the input signal S_{IN}, which are caused by changes in the power supply voltage V_{DD} output from the switching power supply 40. More specifically, the correction memory 51 may store, as the correction pattern D_{CORR}, pattern data that causes the control signal S_{CONT} to change with an inverse phase relative to the change in the power supply voltage V_{DD} supplied from the switching power supply 40 to the output circuit 20.

If the change in the power supply voltage V_{DD} from the switching power supply 40 depends on the power consumed by the output circuit 20, the correction memory 51 may store a plurality of correction patterns D_{CORR} corresponding to amounts of power consumed by the output circuit 20.

The correction pattern acquiring section 52 acquires each piece of data in the correction pattern D_{CORR} stored by the correction memory 51, according to the repeating period of the timing clock CLK_{TMG-1} from the timing clock generating section 30, and outputs a correction signal S_{CORR} corresponding to this correction pattern D_{CORR} to the correction pattern adder 55. If the correction memory 51 stores a plurality of correction patterns D_{CORR} as described above, the correction pattern acquiring section 52 may acquire a correction pattern D_{CORR} corresponding to the amount of power consumed by the output circuit 20.

The control signal generating section 57 generates the prescribed control signal S_{CONT} and outputs this signal to the correction pattern adder 55. The control signal generating section 57 may generate the control signal S_{CONT} based on a setting value that is set in advance according to the change amount that the output circuit 20 applies to the characteristic of the input signal S.

The offset memory 53 stores a prescribed offset value to be added to the control signal S_{CONT}. The offset memory 53 may store an offset value for correcting a unique characteristic of the output circuit 20. More specifically, the offset memory 53 may store an offset value for correcting deviation between an expected change amount and the change amount that the output circuit 20 applies to the characteristic of the input signal S_{IN} according to the power supply voltage V_{DD}. If a plurality of the signal output circuits 10 according to the present embodiment are provided and each output circuit 20 outputs an output signal S_{OUT} to an input pin of a certain IC or LSI, the offset memory 53 of each signal output circuit 10 may store an offset value for correcting an error in the input timing of the output signal S_{OUT} to the input pin caused by differences in line length between the output circuit 20 and each of the input pins. This offset value may be added to the control signal S_{CONT} and the resulting signal may be supplied to the output circuit 20, as described further below.

The correction pattern adder 55 adds the correction signal S_{CORR} from the correction pattern acquiring section 52 to the control signal S_{CONT} from the control signal generating section 57, and outputs the resulting signal to the offset adder 56. The offset adder 56 adds the offset value S_{CONT} stored in the offset memory 53 to the control signal S_{CONT} from the correction pattern adder 55, and outputs the resulting signal to the output circuit 20. In this way, the control signal S_{CONT} output by the control signal generating section 57 has the correction signal SCORR, which corresponds to the correction pattern D_{CORR} stored in the output signal S_{OUT} output by the memory correction memory 51, and the offset value S_{OFST} stored in the offset memory 53 superimposed thereon by the superimposing section 54, and is then output to the output circuit 20.

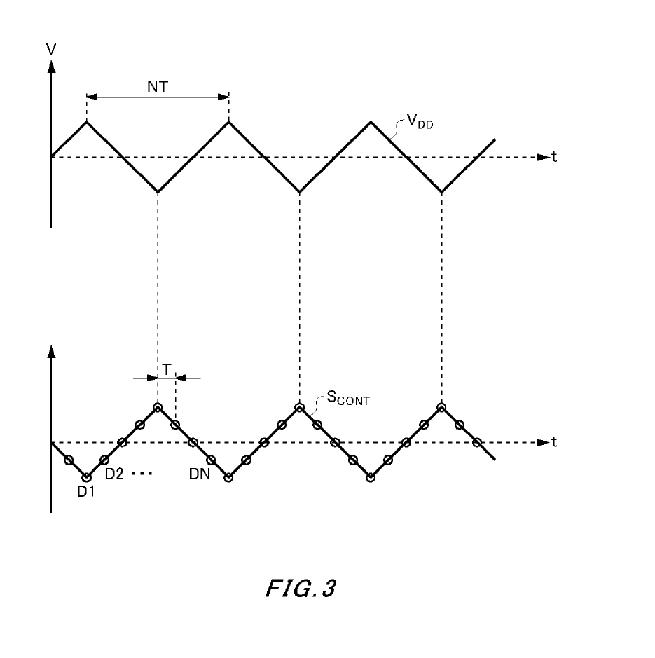

FIG. 3 shows an exemplary phase relationship between a waveform of the power supply voltage V_{DD} supplied from the switching power supply 40 to the output circuit 20 and a waveform of the control signal S_{CONT} supplied from the control section 50 to the output circuit 20. When the magnitude of the power supply voltage V_{DD} from the switching power supply 40 to the output circuit 20 changes periodically, as shown in FIG. 3, the control section 50 outputs to the output circuit 20 a control signal S_{COR} that changes with the inverse phase of the change in the power supply voltage V_{DD}. In other words, as shown in FIG. 3, the control section 50 outputs to the output circuit 20 a control signal S_{CONT} that increases when the power supply voltage V_{DD} decreases and decreases when the power supply voltage V_{DD} increases.

The correction memory 51 stores each piece of data (D1, D2, D3, etc.) of the correction pattern D_{CORR} for generating the control signal S_{CONT} shown in FIG. 3. The data of this correction pattern D_{CORR} may be digital data indicating a value of the control signal S_{CONT} when sampled at prescribed time intervals T. As described above, the waveform of the correction pattern preferably changes with the inverse phase of the waveform of the power supply voltage V_{DD}. The waveform of the correction pattern may differ from the waveform of the power supply voltage V_{DD} by 180 degrees. The waveform of the correction pattern may have a minimum value when the power supply voltage V_{DD} is at maximum value and a maximum value when the power supply voltage V_{DD} is at a minimum value, as shown in FIG. 3.

The correction memory 51 may store N pieces of data (D1, D2, . . . , DN) as the correction pattern. The correction memory 51 may output a periodic correction pattern by repeatedly outputting these N pieces of data. In this case, with the switching period of the switching power supply 40 being NT, the correction memory 51 sequentially output the pieces of data with a period T that is 1/N.

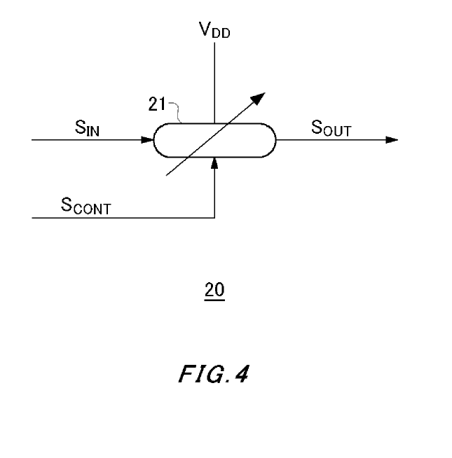

FIG. 4 is a schematic view showing an exemplary configuration of the output circuit 20. The following describes an example in which the output circuit 20 includes a delay circuit 21 having one stage, but the output circuit 20 is not limited to this configuration. For example, the output circuit 20 may have one or more elements including a delay circuit, an amplification circuit, and a frequency modulation circuit.

The delay circuit 21 delays the input signal S_{IN} by a prescribed delay amount, and outputs the resulting signal as the output signal S_{OUT}. The delay amount that the delay circuit 21 applies to the input signal S_{IN} may change according to changes in the magnitude of the power supply voltage V_{DD}.

The delay amount of the delay circuit 21 is controlled by the control signal S_{CONT} from the control section 50. As described above, the control signal S_{CONT} includes the correction pattern D_{CORR} for decreasing the change in the delay amount caused by the change in the power supply voltage V_{DD}. Accordingly, even when the power supply voltage V_{DD} changes due to ripple noise or the like caused by the switching operation of the switching power supply 40, the change in the delay amount due to this voltage change can be decreased by having the control signal S_{CONT} change with the inverse phase of the change of the switching power supply 40.

Instead of the example used for the present embodiment, when the output circuit 20 includes an amplification circuit or a frequency modulation circuit, the gain by which the amplification circuit amplifies the amplitude of the input signal S_{IN} or the ratio by which the frequency modulation circuit modulates the frequency of the input signal S_{IN} may be set according to the magnitude of the power supply voltage V_{DD}, and controlled by the control signal S_{CONT} from the control section 50. Even when the gain of the amplification circuit and the modulation ratio of the frequency modulation circuit change due to changes in the power supply voltage V_{DD}, this change can be suppressed by the control signal S_{CONT}.

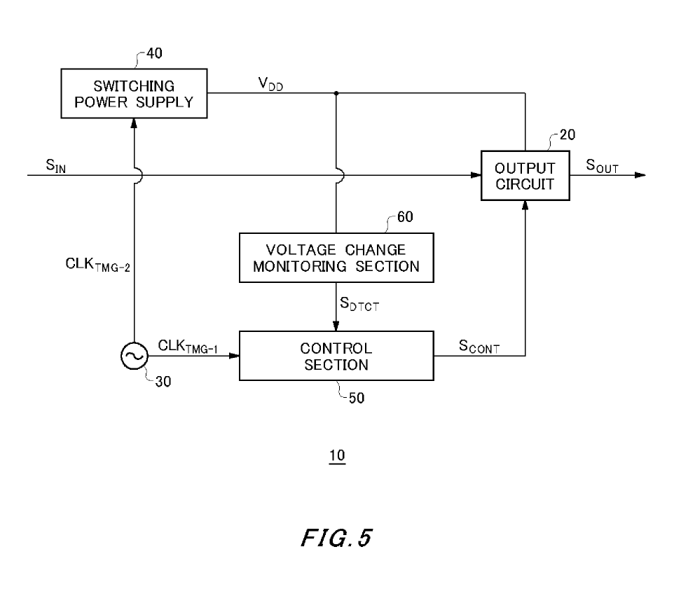

FIG. 5 is a schematic view showing another exemplary configuration of the signal output circuit 10. Components in the signal output circuit 10 of the present embodiment that are the same as those of the signal output circuit 10 described above are given the same reference numerals and further description is omitted.

The signal output circuit 10 of the present embodiment further includes a voltage change monitoring section 60 that detects the power supply voltage V_{DD} supplied from the switching power supply 40 to the output circuit 20, and monitors the change in this power supply voltage V_{DD}. The voltage change monitoring section 60 outputs to the control section 50 a power supply voltage detection signal S_{DTCT} indicating detection results of the power supply voltage V_{DD}. The voltage change monitoring section 60 may output, as the power supply voltage detection signal S_{DTCT}, digital data indicating a waveform detected for the power supply voltage V_{DD} or data indicating changes in the power supply voltage V_{DD} that exceed a predetermined reference amount.

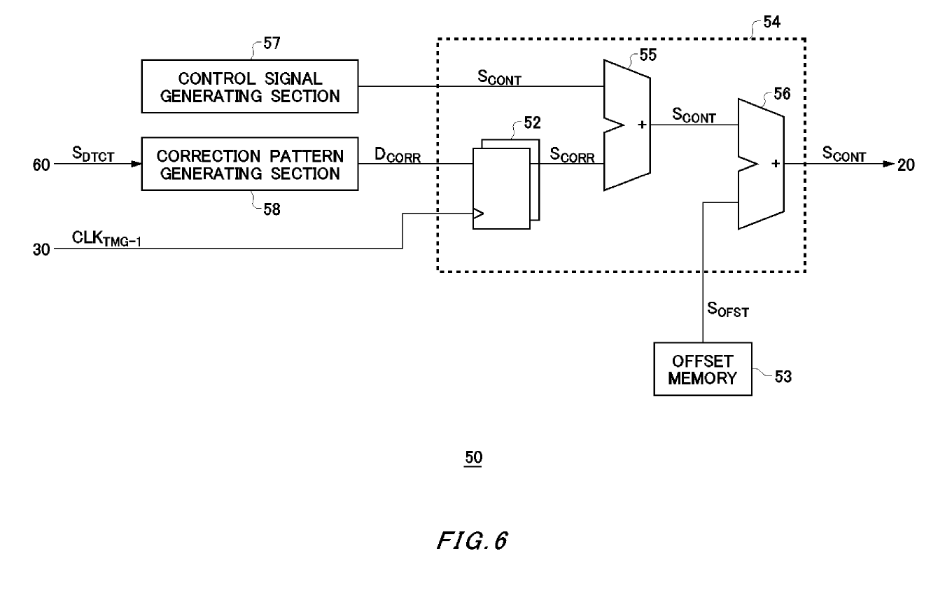

The control section 50 generates the control signal S_{CONT} based on CLK_{TMG-1} from the timing clock generating section 30 and the power supply voltage detection signal S_{DTCT} from the voltage change monitoring section 60, and outputs the control signal S_{CONT} to the output circuit 20. A detailed example of the configuration of the control section 50 is provided further below with reference to FIG. 6.

FIG. 6 is a schematic view showing an exemplary configuration of the control section 50 in the signal output circuit 10 shown in FIG. 5. Components in the control section 50 of the present embodiment that are the same as those of the control section 50 described above are given the same reference numerals and further description is omitted.

The control section 50 of the present embodiment includes a correction pattern generating section 58 instead of the correction memory 51 included in the control section 50 described above in relation to FIGS. 1 and 2. The correction pattern generating section 58 receives the power supply voltage detection signal S_{DTCT} from the voltage change monitoring section 60 and generates the correction pattern D_{CORR} corresponding to the power supply voltage detection signal S_{DTCT}. If the power supply voltage detection signal S_{DTCT} is digital data indicating the waveform of the power supply voltage V_{DD}, the correction pattern generating section 58 may generate the correction pattern D_{CORR} to have a waveform with an inverse phase of the waveform of the power supply voltage V_{DD}.

By including the correction pattern generating section 58, the control section 50 of the present embodiment can change the control signal S_{CONT} based on the correction pattern D_{CORR} generated according to the power supply voltage detection signal S_{DTCT}, which indicates changes in the power supply voltage V_{DD} in real time, sent from the voltage change monitoring section 60. Accordingly, changes in the change amount applied to the characteristic of the input signal S_{IN} by the output circuit 20, which are caused by changes in the power supply voltage V_{DD}, can be more reliably suppressed.

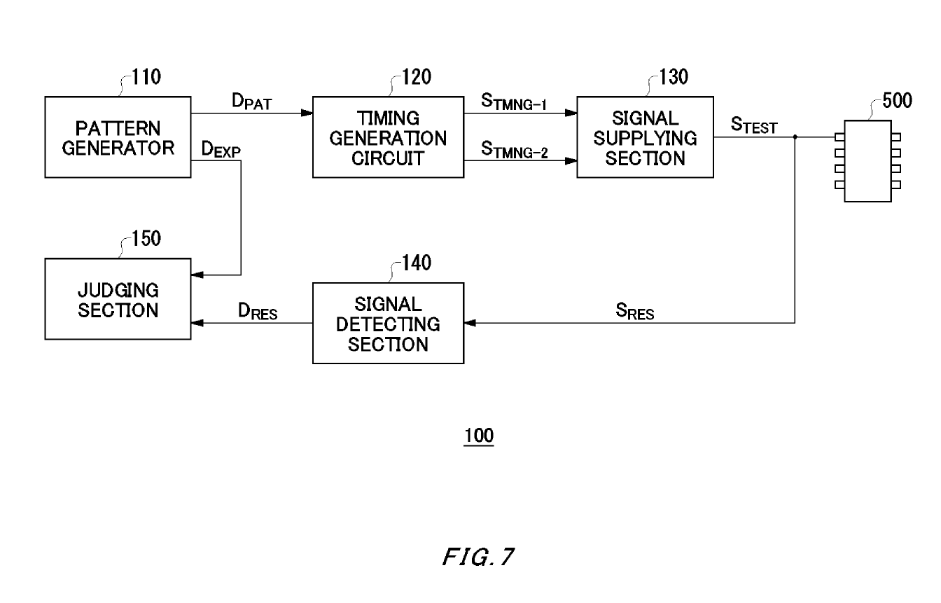

FIG. 7 shows an exemplary configuration of a test apparatus 100 according to another embodiment of the present invention. The test apparatus 100 tests a device under test 500 such as a semiconductor circuit, and includes a pattern generator 110, a timing generation circuit 120, a signal supplying section 130, a signal detecting section 140, and a judging section 150.

The pattern generator 110 generates a test pattern D_{PAT}, which is pattern data corresponding to a test program for testing the device under test 500, and transmits the test pattern D_{PAT} to the timing generation circuit 120. The pattern generator 110 also generates an expected value pattern D_{EXP}, which is pattern data corresponding to the test pattern D_{PAT}, and transmits the expected value pattern D_{EXP} to the judging section 150.

The timing generation circuit 120 generates timing signals S_{TMNG-1} and S_{TMNG-2} designating edge timings of the test signal S_{TEST} supplied to the device under test 500, based on the test pattern D_{PAT} from the pattern generator 110, and transmits these timing signals to the signal supplying section 130.

The signal supplying section 130 generates the test signal S_{TEST} to have timings corresponding to the timing signals S_{TMNG-1} and S_{TMNG-2} from the timing generation circuit 120 as boundaries at which the data transitions, and inputs the test signal S_{TEST} to the device under test 500. The signal supplying section 130 may generate a test signal S_{TEST} that transitions from logic L to logic H according to the timing of the timing signal S_{TMNG-1} and transitions from logic H to logic L according to the timing of the timing signal S_{TMNG-2}. The signal supplying section 130 may include an SR flip-flop or the like that causes the output level to transition from logic L to logic H or from logic H to logic L according to rising edges of the timing signals S_{TMNG-1} and S_{TMNG-2}.

The signal detecting section 140 detects the logic level of a response signal S_{RES} output by the device under test 500, and outputs this logic level to the judging section 150 as response data D_{RES}. The signal detecting section 140 includes one or more level comparators, and may detect whether the logic level of the response signal S_{RES} at a prescribed timing corresponds to logic H or logic L. In this case, the signal detecting section 140 may output a time sequence of the logic pattern obtained from the detection results to the judging section 150 as the response data D_{RES}.

The judging section 150 judges pass/fail of the device under test 500 based on the detection results of the response signal S_{RES} by the signal detecting section 140. The judging section 150 may judge pass/fail of the device under test 500 by comparing the response data D_{RES} from the signal detecting section 140 to the expected value pattern D_{EXP} from the pattern generator 110.

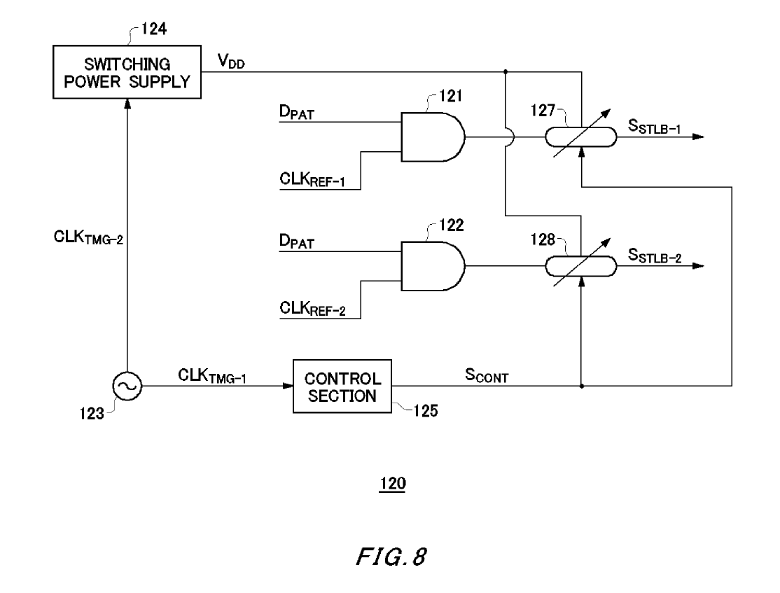

FIG. 8 shows an exemplary configuration of the timing generation circuit 120. The timing generation circuit 120 includes pulse selecting sections 121 and 122, a timing clock generating section 123, a switching power supply 124, a control section 125, a delay circuit 127, and a delay circuit 128.

In the timing generation circuit 120 of the present embodiment, the timing clock generating section 123, the switching power supply 124, and the control section 125 correspond respectively to the timing clock generating section 30, the switching power supply 40, and the control section 50 of the signal output circuit 10 described above, and since these components have the substantially the same functions, further description is omitted.

The pulse selecting section 121 acquires the test pattern D_{PAT} from the pattern generator 110 at the timing of CLK_{REF-1}, and outputs a timing signal S_{TMNG-1} corresponding to the acquisition results. Here, CLK_{REF-1} may be a timing signal with a timing corresponding to a test cycle used when testing the device under test 500.

Accordingly, the pulse selecting section 121 detects the test pattern D_{PAT} from the pattern generator 110 in each test cycle, and may output the timing signal S_{TMNG-1} when a value corresponding to logic H is read from the test pattern D_{PAT}. Here, CLK_{REF-1} may be generated by a signal generation circuit in the test apparatus 100 according to a test program.

The pulse selecting section 122 acquires the test pattern D_{PAT} from the pattern generator 110 at the timing of CLK_{REF-2}, in the same manner as the pulse selecting section 121, and outputs the timing signal S_{TMNG-2} corresponding to the acquisition results. Here, CLK_{REF-2} may be a timing signal having the same timing as CLK_{REF-1}.

Accordingly, the pulse selecting section 122 may output the timing signal S_{TMNG-2} when a value corresponding to logic H is read from the test pattern D_{PAT} according to the test cycle. Here, CLK_{REF-2} may be generated by a signal generation circuit in the test apparatus 100 according to the test program, in the same manner as CLK_{REF-1}.

The switching power supply 124 switches the power supply ON and OFF according to the frequency of CLK_{TMG} from the timing clock generating section 123, and outputs the power supply voltage V_{DD} as a root mean square value to the delay circuits 127 and 128. The control section 125 outputs the prescribed control signal S_{CONT} to the delay circuits 127 and 128. The control section 125 may output the control signal S_{CONT} to control the delay amount applied by the delay circuit 127 to the timing signal S_{TMNG-1} from the pulse selecting section 121 and the delay amount applied by the delay circuit 128 to the timing signal S_{TMNG-2} from the pulse selecting section 122.

The control section 125 may change the control signal S_{CONT} based on change in the power supply voltage V_{DD}. The control section 125 may individually control the delay amounts of the delay circuit 127 and the delay circuit 128 by outputting different control signals S_{CONT} to the delay circuit 127 and the delay circuit 128. In this case, the control section 125 may add an offset value for correcting the unique characteristics of each delay circuit to the respective control signals S_{CONT} output by the delay circuit 127 and the delay circuit 128.

The delay circuit 127 and the delay circuit 128 respectively delay the timing signal S_{TMNG-1} from the pulse selecting section 121 and the timing signal S_{TMNG-2} from the pulse selecting section 122 by a prescribed delay amount, and output the resulting signals. Here, the delay amount that the delay circuit 127 applies to the timing signal S_{TMNG-1} and the delay amount that the delay circuit 128 applies to the timing signal S_{TMNG-2} may both be set according to the magnitude of the power supply voltage V_{DD}. The delay amounts of the delay circuit 127 and the delay circuit 128 may change according to changes in the magnitude of the power supply voltage V_{DD}.

In the present embodiment, the delay circuit 127 may delay the timing signal S_{TMNG-1} such that the timing of the rising edge of the timing signal S_{TMNG-1} from the pulse selecting section 121 substantially matches the timing at which the test signal S_{TEST} supplied to the device under test 500 transitions from logic L to logic H. The delay circuit 128 may delay the timing signal S_{TMNG-2} such that the timing of the rising edge of the timing signal S_{TMNG-2} from the pulse selecting section 122 substantially matches the timing at which the test signal S_{TEST} supplied to the device under test 500 transitions from logic H to logic L.

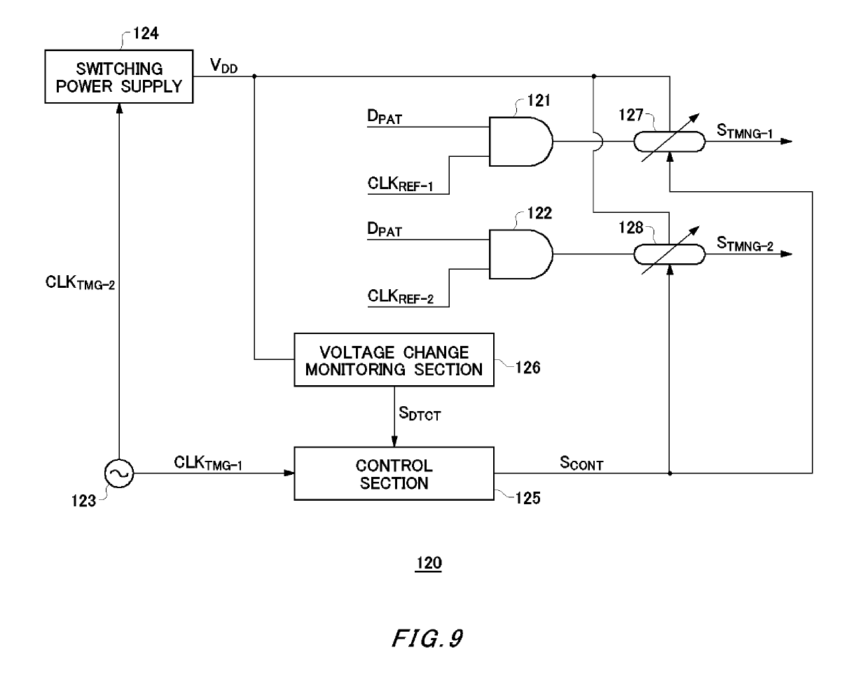

FIG. 9 shows another exemplary configuration of the timing generation circuit 120. The timing generation circuit 120 of the present embodiment further includes a voltage change monitoring section 126 in addition to the configuration of the timing generation circuit 120 described above.

The voltage change monitoring section 126 outputs to the control section 125 a power supply voltage detection signal S_{DTCT} indicating detection results of the power supply voltage V_{DD} output from the switching power supply 124. The voltage change monitoring section 126 may output, as the power supply voltage detection signal S_{DTCT}, digital data indicating a waveform detected for the power supply voltage V_{DD} or data indicating changes in the power supply voltage V_{DD} that exceed a predetermined reference amount.

The control section 125 generates the control signal S_{CONT} based on CLK_{TMG-4} from the timing clock generating section 30 and the power supply voltage detection signal S_{DTCT} from the voltage change monitoring section 126, and outputs the control signal S_{CONT} to the output circuit 20. The remaining configuration of the timing generation circuit 120 of the present embodiment has substantially the same function as the timing generation circuit 120 described above that does not include the voltage change monitoring section 126, and therefore further description is omitted.

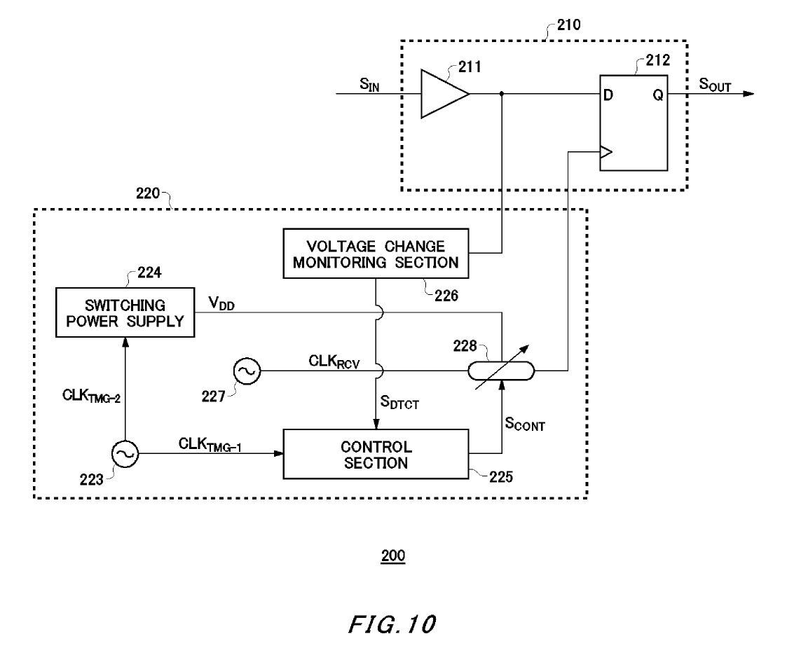

FIG. 10 shows an exemplary configuration of a receiver circuit 200 according to another embodiment of the present invention. The receiver circuit 200 detects the data pattern of the input signal S_{IN}, and includes a digital converting section 210 and a clock generation circuit 220.

The digital converting section 210 detects the logic value of the input signal S_{IN} according to a received clock signal CLK_{RCV} from the clock generation circuit 220. The digital converting section 210 includes a signal detecting section 211 and a signal acquiring section 212.

The clock generation circuit 220 generates the received clock signal CLK_{RCV} to have a predetermined phase. The clock generation circuit 220 includes a timing clock generating section 223, a switching power supply 224, a control section 225, a change monitoring section 226, a received clock generating section 227, and a delay circuit 228.

In the clock generation circuit 220, the timing clock generating section 123, the timing clock generating section 223, the switching power supply 224, and the control section 225 correspond respectively to the timing clock generating section 30, the switching power supply 40, and the control section 50 of the signal output circuit 10 described above, and since these components have substantially the same functions, further description is omitted.

The signal detecting section 211 receives the input signal S_{IN} and outputs to the signal acquiring section 212 a detection signal indicating a logic value corresponding to the signal level of the input signal S. The signal detecting section 211 may output to the signal acquiring section 212 a detection signal having a pulse waveform that transitions from logic L to logic H at a timing when the signal level of the input signal S_{IN} exceeds a prescribed reference level and transitions from logic H to logic L at a timing when the signal level of the input signal S_{IN} drops below the prescribed reference level.

The signal acquiring section 212 acquires the detection signal from the signal detecting section 211 according to the timing of the received clock signal CLK_{RCV} from the clock generation circuit 220, and outputs the digital data S_{OUT}, which is a binary data sequence corresponding to the signal level of the detection signal. The signal acquiring section 212 may output the digital data S_{OUT} to an external display apparatus or storage apparatus of the receiver circuit 200. The digital converting section 210 further includes a memory downstream from the signal acquiring section 212, and may store the digital data Sour output from the signal acquiring section 212 in this memory.

If the input signal S_{IN} has a signal level corresponding to multi-valued data having three or more values, the signal detecting section 211 may detect each signal level of the input signal S_{IN} and output to the signal acquiring section 212 a detection signal having multi-valued levels corresponding to the signal levels. In this case, the signal acquiring section 212 may acquire the multi-valued level detection signal according to the timing of the received clock signal CLK_{RCV}, and output a multi-valued data sequence corresponding to the signal levels.

The switching power supply 224 switches the power supply ON and OFF according to the frequency of CLK_{TMG} from the timing clock generating section 223, and outputs the power supply voltage V_{DD} as a root mean squared value to the delay circuit 228. The control section 225 generates the prescribed control signal S_{CONT} based on CLK_{TMG} from the timing clock generating section 223 and the change detection signal S_{DTCT} from the change monitoring section 226, and outputs the control signal S_{CONT} to the delay circuit 228. The control section 225 may output the control signal S_{CONT} to control the delay amount applied by the delay circuit 228 to the timing received clock signal CLK_{RCV} from the received clock generating section 227. The control section 225 may change the control signal S_{CONT} based on changes in the power supply voltage V_{DD}.

The change monitoring section 226 detects the timing at which the logic level of the detection signal from the signal detecting section 211 transitions, which is the edge timing of the pulse waveform of the detection signal, and monitors the change thereof, i.e. the timing jitter in the detection signal. The change monitoring section 226 outputs to the control section 225 the change detection signal S_{DTCT} indicating the detection results of the edge timing in the detection signal from the signal detecting section 211.

The control section 225 may further adjust the control signal S_{CONT} such that the timing of the received clock signal CLK_{RCV} follows the changes in the edge timing, which are due to timing jitter in the input signal S_{IN} caused by transmission delay and disturbance, for example. More specifically, the control section 225 may adjust the control signal S_{CONT} based on the change detection signal S_{DTCT} from the change monitoring section 226 such that the delay amount of the delay circuit 228 changes with the same phase as the change in the edge timing described above. As a result, even when the edge timing of the detection signal from the signal detecting section 211 changes, the signal acquiring section 212 can reliably acquire the detection signal using the received clock signal CLK_{RCV}.

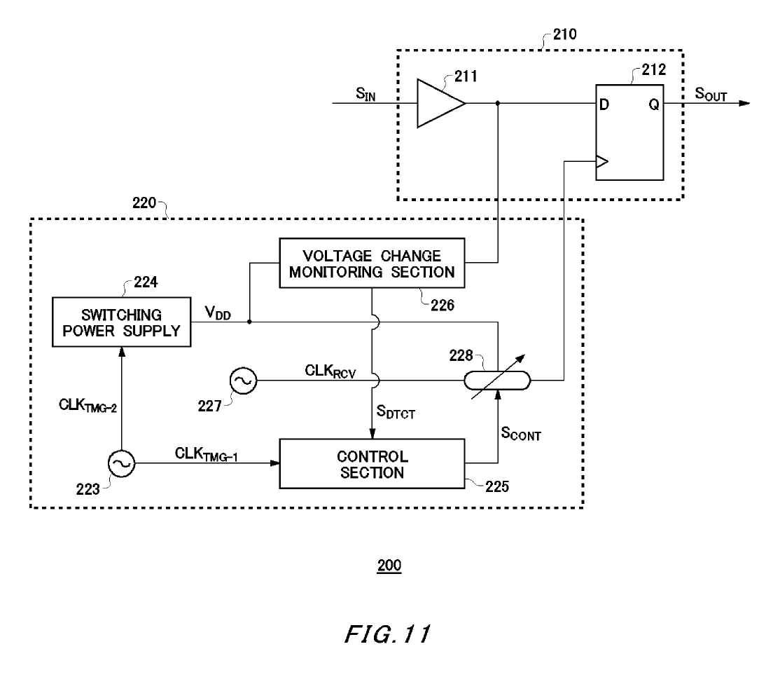

FIG. 11 shows another exemplary configuration of the receiver circuit 200. In the receiver circuit 200 of the present embodiment, in addition to the edge timing in the pulse waveform of the detection signal from the signal detecting section 211, the change monitoring section 226 also detects the power supply voltage V_{DD} supplied from the switching power supply 224 to the delay circuit 228, and monitors the change in this power supply voltage V_{DD}. The change monitoring section 226 outputs to the control section 225 the detection results of the power supply voltage V_{DD} from the switching power supply 224 and the change detection signal S_{DTCT} indicating the detection results of the edge timings in the detection signal from the signal detecting section 211.

The control section 225 may change the control signal S_{CONT} based on changes in the power supply voltage V_{DD}. More specifically, the control section 225 may change the control signal S_{CONT} based on the change in the detection signal S_{DTCT} from the change monitoring section 226, in a manner to suppress changes in the delay amount applied by the delay circuit 228 to the received clock signal CLK_{RCV}, which are caused by change in the power supply voltage V_{DD} over time or change in power supply voltage V_{DD} due to ripple noise corresponding to the operational period of the switching power supply 40. As a result, even when the power supply voltage V_{DD} changes, the change in the delay amount caused by this change can be decreased.

In the present embodiment, the control section 225 may further adjust the control signal S_{CONT} such that the timing of the received clock signal CLK_{RCV} follows the changes in the edge timing, which are due to timing jitter in the input signal S_{IN} caused by transmission delay and disturbance, for example. As a result, even when the edge timing of the detection signal from the signal detecting section 211 changes, the signal acquiring section 212 can reliably acquire the detection signal using the received clock signal CLK_{RCV}.

While the embodiments of the present invention has (have) been described, the technical scope of the invention is not limited to the above described embodiment(s). It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A signal output circuit that outputs a signal, comprising:
an output circuit that changes a characteristic of a signal output therefrom according to a change in power supply voltage supplied thereto and a control signal supplied thereto; and
a control section that changes the control signal to compensate for a change in the characteristic due to a change in the power supply voltage.

2. The signal output circuit according to claim 1, further comprising a switching power supply that generates the power supply voltage, wherein
the control section is supplied in advance with a correction pattern corresponding to a change in the power supply voltage, and changes the control signal based on the correction pattern.

3. The signal output circuit according to claim 2, wherein the control section includes:
a correction memory that stores the correction pattern; and
a superimposing section that superimposes a signal corresponding to the correction pattern onto the control signal.

4. The signal output circuit according to claim 3, wherein
the correction memory stores, as the correction pattern, digital data indicating a waveform of the correction pattern, and
the superimposing section reads the digital data with a frequency corresponding to a switching frequency of the switching power supply.

5. The signal output circuit according to claim 4, wherein the correction memory stores the correction pattern having a waveform with a phase that is the inverse of a phase of the power supply voltage generated by the switching power supply.

6. The signal output circuit according to claim 3, wherein
the correction memory stores in advance a plurality of types of the correction patterns, and
the superimposing section reads the correction pattern that corresponds to power consumed by the output circuit.

7. The signal output circuit according to claim 1, wherein
the output circuit includes a delay circuit that delays a signal supplied thereto by a delay amount corresponding to the control signal, and outputs the resulting delayed signal.

8. The signal output circuit according to claim 1, further comprising a voltage change monitoring section that monitors change in the power supply voltage supplied to the output circuit, wherein
the control section changes the control signal to compensate for a change in the characteristic due to a change in the power supply voltage detected by the voltage change monitoring section.

9. The signal output circuit according to claim 8, wherein
the control section changes the control signal based on a correction pattern having a waveform with a phase that is the inverse of a phase of a waveform of the power supply voltage detected by the voltage change monitoring section.

10. A timing generation circuit that generates a timing signal having a predetermined phase, comprising:
a delay circuit that outputs the timing signal by delaying an input signal by a delay amount corresponding to a control signal supplied thereto, and that changes the delay amount according to a change in power supply voltage supplied thereto; and
a control section that changes the control signal to compensate for a change in the delay amount caused by a change in the power supply voltage.

11. A test apparatus that tests a device under test, comprising:
the timing generation circuit according to claim 10 that generates the timing signal having a predetermined phase;
a signal supplying section that generates a test signal having a phase corresponding to the timing signal and supplies the test signal to the device under test; and
a judging section that judges pass/fail of the device under test by detecting operation of the device under test according to the test signal.

12. A receiver circuit that detects a data pattern of an input signal, comprising:
a digital converting section that detects a logic value of the input signal according to a clock signal supplied thereto; and
a clock generation circuit that generates the clock signal having a predetermined phase, wherein the clock generation circuit includes:
a delay circuit that outputs the clock signal by delaying a reference signal by a delay amount corresponding to a control signal supplied thereto, and that changes the delay amount according to a change in power supply voltage supplied thereto; and
a control section that changes the control signal to compensate for the change in the delay amount caused by a change in the power supply voltage.

13. The receiver circuit according to claim 12, wherein
the control section further adjusts the control signal supplied to the delay circuit to follow a change in an edge of the input signal.
